(19) United States
(12) Patent Application Publication
(10) Pub. No.: US 2023/0197418 A1
(43) Pub. Date: Jun. 22, 2023

(54) SELECTIVE DEPOSITION ENABLED BY VAPOR PHASE INHIBITOR

(71) Applicant: INTERNATIONAL BUSINESS MACHINES CORPORATION, Armonk, NY (US)

(72) Inventors: Rudy J. Wojtecki, San Jose, CA (US); Krystelle Lionti, San Jose, CA (US); Noel Arellano, Gilroy, CA (US); SON NGUYEN, Schenectady, NY (US)

(21) Appl. No.: 17/556,242

(22) Filed: Dec. 20, 2021

(51) Int. Cl. H01J 37/32

(52) U.S. Cl. CPC H01J 37/32522; H01J 37/32009; H01J 2237/332

(57) ABSTRACT

A method of selectively forming a cover layer is provided. The method includes exposing a surface of a metal feature and a surface of a dielectric layer to a plasma treatment, and exposing the surface of a metal feature and a surface of a dielectric layer to an inhibitor species to form an inhibitor layer selectively on the surface of the metal feature. The method further includes polymerizing the inhibitor layer to form an inhibiting film, and forming the cover layer on the surface of the dielectric layer.

### BACKGROUND

The present invention generally relates to inhibiting materials, and more particularly to the use of vapor phase inhibitors in area selective deposition.

Area selective depositions allow formation of layers on particular portions of a surface based on the materials of the surfaces. Area-selective deposition can be a chemical or physical process that controllably forms the desired material layer on the desired growth surface. The selectivity can come from surface modifications of the substrate that allow or prevent the deposition material precursor from adsorbing on some of the surfaces.

### SUMMARY

In accordance with an embodiment of the present invention, a method of selectively forming a cover layer is provided. The method includes exposing a surface of a metal feature and a surface of a dielectric layer to a plasma treatment, and exposing the surface of a metal feature and a surface of a dielectric layer to an inhibitor species to form an inhibitor layer selectively on the surface of the metal feature. The method further includes polymerizing the inhibitor layer to form an inhibiting film, and forming the cover layer on the surface of the dielectric layer.

In accordance with another embodiment of the present invention, a method of selectively forming a cover layer is provided. The method includes exposing a surface of a metal feature and a surface of a dielectric layer to a reducing plasma treatment, wherein the metal feature is made of a metal selected from the group consisting of copper (Cu), tungsten (W), and cobalt (Co), and exposing the surface of a metal feature and a surface of a dielectric layer to an inhibitor species to form an inhibitor layer selectively on the surface of the metal feature. The method further includes polymerizing the inhibitor layer to form an inhibiting film, and forming the cover layer on the surface of the dielectric layer.

In accordance with yet another embodiment of the present invention, a method of selectively forming a cover layer is provided. The method includes exposing a surface of a metal feature and a surface of a dielectric layer to a reducing plasma treatment, wherein the metal feature is made of a metal selected from the group consisting of copper (Cu), tungsten (W), and cobalt (Co), and exposing the surface of a metal feature and a surface of a dielectric layer to an inhibitor species to form an inhibitor layer selectively on the surface of the metal feature. The method further includes polymerizing the inhibitor layer to form an inhibiting film, and forming the cover layer on the surface of the dielectric layer, wherein the cover layer is a dielectric material selected from the group consisting of zinc oxide (ZnO), tantalum nitride (TaN), and aluminum oxide (AlO).

These and other features and advantages will become apparent from the following detailed description of illustrative embodiments thereof, which is to be read in connection with the accompanying drawings.

### BRIEF DESCRIPTION OF THE DRAWINGS

The following description will provide details of preferred embodiments with reference to the following figures wherein:

FIG. 1 is a cross-sectional side view showing a metal feature in a dielectric layer, in accordance with an embodiment of the present invention;

FIG. 2 is a cross-sectional side view showing a plasma treatment of the exposed surfaces, in accordance with an embodiment of the present invention;

FIG. 3 is a cross-sectional side view showing an inhibitor layer selectively formed on the exposed metal surface, in accordance with an embodiment of the present invention;

FIG. 4 is a cross-sectional side view showing the inhibitor layer forming an inhibiting film on the metal surface, in accordance with an embodiment of the present invention;

FIG. 5 is a cross-sectional side view showing area selective formation of a cover layer on the exposed dielectric surfaces, in accordance with an embodiment of the present invention;

FIG. 6 is a cross-sectional side view showing removal of the inhibitor layer to expose the underlying metal feature, in accordance with an embodiment of the present invention;

FIG. 7 is a cross-sectional side view showing formation of an electrical connection on the underlying metal feature, in accordance with an embodiment of the present invention;

FIG. 8 is a block/flow diagram showing a method of area selective formation of a cover layer utilizing an inhibitor to avoid or reduce lateral overgrowth of a metal surface by the cover layer material, in accordance with an embodiment of the present invention;

FIG. 9 is a top view showing exposed metal surfaces surrounded by a selectively deposited cover layer material, in accordance with an embodiment of the present invention; and

FIG. 10 is a cross-sectional side view showing area selective formation of the cover layer on the dielectric surfaces, in accordance with an embodiment of the present invention.

### DETAILED DESCRIPTION

Embodiments of the present invention provide selective deposition of a dielectric material on a dielectric surface utilizing an inhibiting material containing an amine moiety, that bonds to a metal surface and does not bond to exposed dielectric or metal oxide surfaces, and a polymerizable moiety, such as an alkene (e.g., vinyl) or alkyne (e.g., ethynyl) group. The inhibiting material is of sufficient molecular weight to enable deposition from the vapor phase to produce an inhibiting layer on the metal surface with a tailorable thickness about or above 1 nanometer (nm). The inhibiting layer can subsequently be used to reduce or avoid lateral overgrowth in the area of the selective deposition process.

In a non-limiting exemplary embodiment, propargyl amine can be used for vapor phase selective coating of a metal surface (e.g., Cu), and at an elevated temperature an alkyne can react with neighboring molecules to polymerize to form an inhibiting film on the metal surface. During atomic layer deposition (ALD) conditions (e.g., 150° C.) the polymerized film prevents growth of a metal oxide film (e.g., ZnO) up to 10 nm with one cycle of inhibitor dosing. Integrated vapor phase inhibitor and ALD (without breaking vacuum) can improve process uniformity in selective film deposition. Stabilization through polymerization or cross-linking presents a unique feature, for example, vinyl pyridine can provide for growth of an inhibiting film with selected thickness to reduce lateral overgrowth.

In various embodiments, a thermal stimulus above 100° C. can be used to crosslink the polymerizable moiety of the inhibitor.

Area selective depositions (ASD) are an enabling technology for advanced nodes (beyond 7 nm) and can address a number of fabrication challenges. Existing process schemes for ASD such as liquid based inhibitors suffer from defectivity including coating non-uniformity and oxidation which can be addressed by integrated strategies (vapor phase inhibitors). ASD can be applied to a number of back-end-of-line (BEOL) applications from a fully-aligned via (FAV) to contact shrink of heating elements for Phase Change Memory (PCM) AI hardware, to barrierless contacts for vias all of which enable continued scaling for BEOL.

Exemplary applications/uses to which the present invention can be applied include, but are not limited to: logic devices and memory devices. Phase Change Memory (PCM) AI hardware.

It is to be understood that aspects of the present invention will be described in terms of a given illustrative architecture and structure; however, other architectures, structures, substrates, materials, and process features and steps can be varied within the scope of aspects of the present invention.

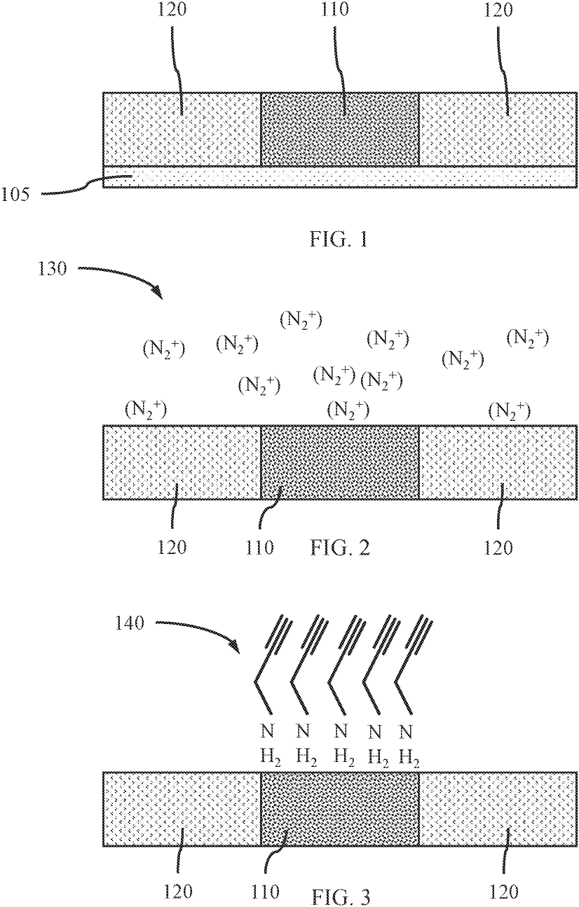

Referring now to the drawings in which like numerals represent the same or similar elements and initially to FIG. 1, FIG. 1 is a cross-sectional side view showing a metal feature in a dielectric layer, in accordance with an embodiment of the present invention.

In one or more embodiments, a metal feature 110 can be formed on a substrate 105 including a dielectric layer 120, where the metal feature 110 can have an exposed surface. The metal feature can be formed in a dielectric layer 120 using lithographic processes, etching, and deposition(s). In various embodiments, the substrate 105 can be a semiconductor substrate, for example, silicon (Si) or silicon-germanium (SiGe), that can include previously fabricated semiconductor devices, where one or more of the metal feature(s) 110 can electrically connect to and/or interconnect the semiconductor devices. The dielectric layer 120 can be grown or deposited on the substrate 105.

In various embodiments, the metal feature 110 can be made of a metal, including, but not limited to, copper (Cu), tungsten (W), and cobalt (Co).

In various embodiments, the dielectric layer 120 can be, for example, a non-metal oxide, including, but not limited to, silicon oxide (SiO), organosilicate glass (SiCOH), carbon doped silicon oxide (SiO:C), fluorine doped silicon oxide (SiO:F), a non-metal nitride, including, but not limited to, silicon nitride (SiN), silicon oxynitride (SiON), silicon boronitride (SiBN), silicon carbonitride (SiCN), silicon boro carbonitride (SiBCN), metal oxides, including, but not limited to, hafnium oxide (HfO), zirconium oxide (ZrO), lanthanum oxide (LaO), niobium oxide (NbO), titanium oxide (TiO), aluminum oxide (AlO), zinc oxide (ZnO), metal nitrides, including, but not limited to, tungsten nitride (WN), titanium nitride (TiN), tantalum nitride (TaN), niobium nitride (NbN), aluminum nitride (A1N), and combinations thereof.

In a non-limiting exemplary embodiment, the dielectric layer 120 can be organosilicate glass (SiCOH), and the metal feature(s) 110 can be made of copper (Cu).

FIG. 2 is a cross-sectional side view showing a plasma treatment of the exposed surfaces, in accordance with an embodiment of the present invention.

In one or more embodiments, the metal feature(s) 110 and dielectric layer 120 can be exposed to a plasma treatment 130, where the plasma treatment 130 can be a remote plasma treatment, an indirect plasma treatment, or a direct plasma treatment. The plasma treatment can be used to clean and prepare (e.g., activate) the surface(s).

In various embodiments, the plasma may be generated with a chemical species, including, but not limited to, nitrogen gas (N₂) hydrogen gas (H₂), ammonia gas (NH₃), and combinations thereof, where the plasma can be a reducing plasma. Oxides on the metal surface(s) can be removed using the reducing plasma treatment, so inhibitor molecules bonds to the metal surface. In various embodiments, the plasma treatment is not an oxidizing plasma treatment.

In a non-limiting exemplary embodiment, a remote N₂ plasma can be used to treat the exposed surfaces of the metal feature(s) 110 and dielectric layer 120, where the remote N₂ plasma can clean the surface of the metal feature(s) 110 and activate the surface of the dielectric layer 120 for subsequent formation of a cover layer.

FIG. 3 is a cross-sectional side view showing an inhibitor layer selectively formed on the exposed metal surface, in accordance with an embodiment of the present invention.

In one or more embodiments, the exposed surfaces can be exposed to an inhibitor species, where the inhibitor species can selectively deposit on the exposed surfaces of the metal feature(s) 110 to form an inhibitor layer 140, which can be a monolayer.

In various embodiments, the surfaces can be exposed to the gaseous inhibitor molecules at a temperature in a range of the boiling point of the inhibitor species to about 60° C., or about 10° C. to about 40° C., or about 25° C., where the temperature of the substrate 105, metal feature(s) 110 and dielectric layer 120 is above the boiling point of the inhibitor species at the pressure of the vacuum chamber to provide for the chemisorption of the inhibitor species without condensing (physisorption) a multilayer of the inhibitor species on the surface of the metal feature(s) or across both metal and dielectric surfaces.

In various embodiments, the deposition temperature for the gaseous inhibitor can be at or below 60° C. or below 50° C. or at about 25° C. to avoid coating of the dielectric layer surfaces, where the maximum temperature can depend on the inhibitor species used, for example, vinyl pyridine may be deposited at about 60° C. under a reduced pressure of about 1 Torr to about 5 Torr.

In one or more embodiments, the inhibitor species can be a molecule including an amine moiety and a polymerizable moiety, where the polymerizable moiety, for example, a carbon-carbon double bond (vinyl, alkene) or triple bond (propargyl, alkyne) can be attached at the “1” position (i.e., at a terminal position) of a carbon chain. In various embodiments, the carbon chain of the aliphatic molecules can have a length of from 1 to 5 carbons. In various embodiments, the carbon chain can be branched, for example, isopropyl amine, isobutyl amine, isopentyl amine, etc.

In various embodiments, the inhibitor species is of sufficient molecular weight to enable deposition from the vapor phase to produce an inhibiting layer on a metal surface with a tailorable thickness, where the thickness can be in a range of about 1 nanometer (nm) to about 5 nm depending on the inhibitor species (e.g., carbon chain length, presence of cyclic groups, etc).

In one or more embodiments, the inhibitor species can be a primary, secondary, or tertiary amine, where the amine moiety can be incorporated into an unsaturated aliphatic molecule (e.g., vinylamine, propargylamine), an aryl molecule (e.g., 4-vinylaniline, 2-vinylpyrrole), or a heterocyclic molecule (4-vinyl pyridine, 4-vinylpiperidine).

In various embodiments, the inhibitor species can be, for example, 4-vinylpyridine, 4-vinylpiperidine, 4-vinylaniline, 2-vinylpyrrole, propargylamine (3-Amino-1-propyne), dipropargylamine (N,N-di(prop-2-ynyl)amine), tripropargylamine (tris(2-propynyl)amine), vinylamine (ethenamine, N-ethenylamine), N,N-diethnylamine (N-vinylethenamine), triethylene amine (N,N-diethenylethenamine), 1-amino-3-butyne, 1-amino-3-butene (3-butenylamine), 1-amino-4-pentyne (4-pentynylamine), or 2-methyl-N-(2-methyl-2-propenyl)-2-propen-1-amine.

The inhibitor species can have different boiling points (at 760 Torr), where for example, 1-amino-3-butene (3-butenylamine) = 83° C.; 1-amino-3-butyne = 100-103° C.; 4-vinylpyridine = 171° C.; propargylamine (3-amino-1-propyne) = 83° C. The boiling points can be less at reduced pressures for the thin film deposition. The boiling point of the inhibitor species at a predetermined pressure can determine the temperature used for deposition, and alternatively, a predetermined reduced pressure can determine the temperature used for deposition of the inhibitor species.

In various embodiments, the amine moiety can selectively chemisorb to the exposed metal surface, where the nitrogen of the amine group can chemically bond to the surface metal atom(s). The inhibitor molecules can form a monolayer on the metal surface, where the polymerizable moiety can extend away from the surface. Having the same carbon chain length (molecular size) allows the polymerizable moiety of adjacent inhibitor molecules to also be adjacent for subsequent reactions, such that the unsaturated moieties can be polymerized.

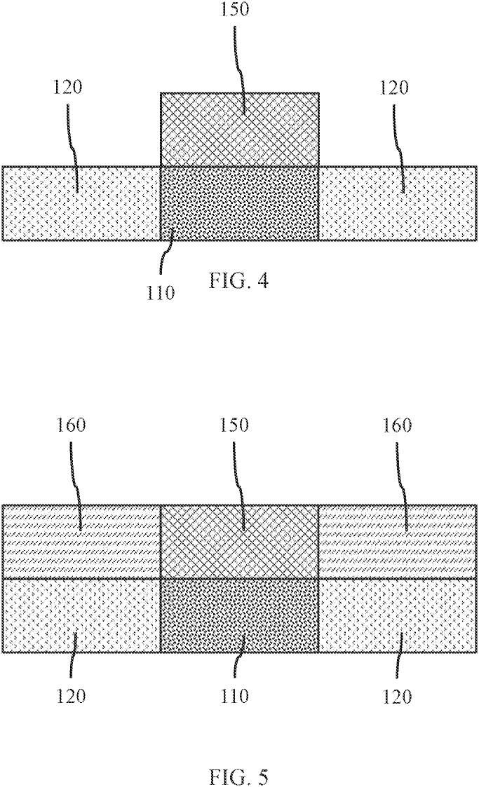

FIG. 4 is a cross-sectional side view showing the inhibitor layer forming an inhibiting film on the metal surface, in accordance with an embodiment of the present invention.

In one or more embodiments, the layer of the inhibitor species can be polymerized by exposing the inhibitor species to a polymerization initiator, including, but not limited to, a thermal stimulus (i.e., temperature), for example, above 100° C. to crosslink the inhibitor molecules, an ultraviolet (wavelength <250 nm) stimulus to crosslink the inhibitor molecules, and/or a chemical stimulus (e.g., Lewis acid) to crosslink the inhibitor molecules. Polymerization of the unsaturated moiety of the inhibitor species can form an inhibiting film 150 selectively on the metal surface of the metal features 110 without forming the inhibiting film 150 on the adjoining regions of the dielectric layer 120.

FIG. 5 is a cross-sectional side view showing area selective formation of a cover layer on the exposed dielectric surfaces, in accordance with an embodiment of the present invention.

In one or more embodiments, a cover layer 160 can be formed on the exposed dielectric surfaces, where the cover layer 160 can be formed by atomic layer deposition (ALD), low pressure chemical vapor deposition (LPCVD), and combinations thereof. The cover layer 160 can be formed selectively on the exposed surfaces of the dielectric layer 120 due to the inhibiting film 150 blocking the surface of the metal feature(s) 110. Plasma enhanced methods, including, but not limited to, plasma enhanced ALD and plasma enhanced chemical vapor deposition (PECVD) may not be used on a monolayer of the inhibitor species, where the plasma can remove the inhibitor molecules from the surface.

In various embodiments, vinyl pyridine can be used with a remote plasma to deposit up to a 10 nm thick cover layer 160.

In various embodiments, the cover layer 160 can be a dielectric material, including, but not limited to, zinc oxide (ZnO), titanium oxide (TiO), aluminum oxide (AlO), silicon carbonitride (SiCN), carbon doped silicon oxide (SiCOH), and combinations thereof.

In various embodiments, the cover layer 160 can have a thickness in a range of about 1 nm to about 15 nm, or about 2 nm to about 10 nm, or about 3 nm to about 8 nm, although other thicknesses are also contemplated.

FIG. 6 is a cross-sectional side view showing removal of the inhibitor layer to expose the underlying metal feature, in accordance with an embodiment of the present invention.

In one or more embodiments, the inhibiting film 150 can be removed to expose the underlying metal feature 110, where the inhibiting film 150 can be removed by ashing and/or a plasma etch. The removal of the polymerized inhibiting film 150 with the cover layer 160 adjacent to the metal feature 110 can allow formation of an electrical connection 170, where the cover layer 160 can prevent the electrical connection 170 from shorting to another adjacent metal feature 110.

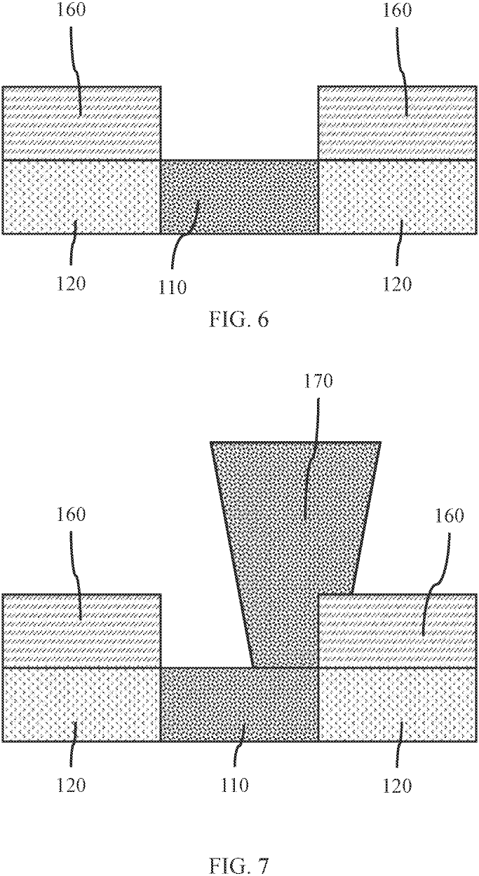

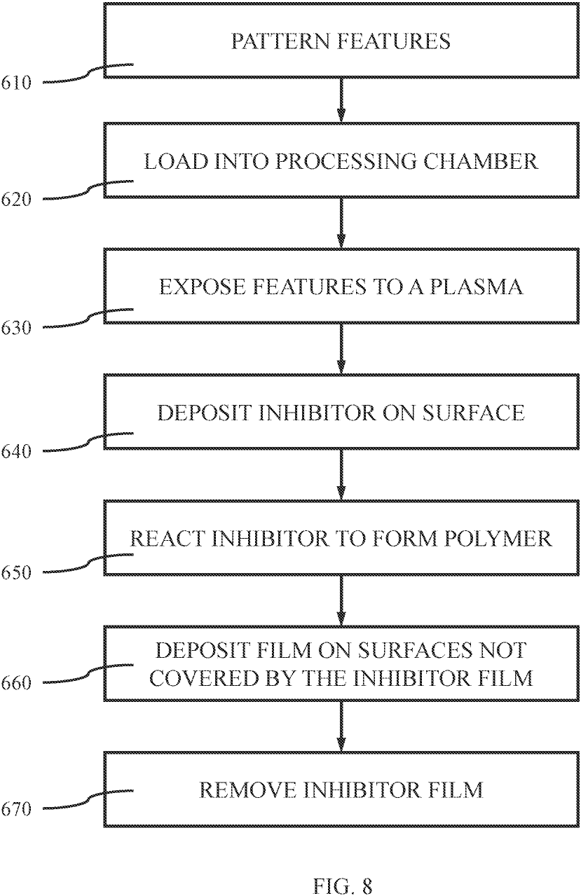

FIG. 7 is a cross-sectional side view showing formation of an electrical connection on the underlying metal feature, in accordance with an embodiment of the present invention.

In one or more embodiments, an electrical connection 170 can be formed on the metal feature 110, where an electrical connection 170 that partially overlaps the cover layer 160 can be prevented from shorting the underlying metal feature 110 with another adjacent metal feature.

FIG. 8 is a block/flow diagram showing a method of area selective formation of a cover layer utilizing an inhibitor to avoid or reduce lateral overgrowth of a metal surface by the cover layer material, in accordance with an embodiment of the present invention.

At block 610, one or more metal features 110 can be formed, where the metal features 110 can be formed in a dielectric layer 120 on a substrate 105. The metal features 110 can be formed by patterning a resist on the surface of the dielectric layer 120 and etching trenches in the dielectric layer 120 using a selective, directional etch, for example, a reactive ion etch (RIE). One or more metals can be deposited into the trenches and a chemical-mechanical polishing (CMP), ammonia and/or hydrogen plasma can be used to remove excess metal from the surfaces.

At block 620, the substrate 105 with the dielectric layer 120 and metal features 110 can be transferred to a processing chamber, for example, a vacuum chamber configured to generate a plasma (direct plasma) or in fluid communication with a plasma source (remote plasma).

At block 630, the dielectric layer 120 and metal features 110 can be exposed to a plasma treatment that can be a direct plasma, an indirect plasma, or a remote plasma. The plasma treatment can clean the surface of the metal feature(s) 110 and activate the surface of the dielectric layer 120, where the plasma treatment can be a reducing plasma treatment that removes metal oxides from the surface of the metal features 110.

In various embodiments, the gaseous species utilized to form the plasma can be nitrogen gas (N₂) hydrogen gas (H₂), ammonia gas (NH₃), and combinations thereof.

In various embodiments, the plasma treatment can be conducted at about room temperature (i.e., 20° C. to about 25° C.).

At block 640, the dielectric layer 120 and metal features 110 can be exposed to a gaseous inhibitor material, where the dielectric layer 120 and metal features 110 can be exposed to the inhibitor material in the vacuum chamber. The gaseous inhibitor material can be dosed into the chamber for a pulse duration and then held for a soak period, for example, a 2.5 second (sec) pulse of inhibitor species into the chamber followed by an 80 sec soak period to allow time to interact with the surfaces.

In various embodiments, the chamber, metal features 110, dielectric layer 120 and substrate 105 can be at a temperature in a range of the boiling point of the inhibitor species to about 60° C., or about 10° C. to about 50° C., or about 25° C., where the gaseous inhibitor material can form a monolayer on the metal surface without condensing the gaseous inhibitor material as a multilayer across the surfaces. The temperature for the inhibitor deposition can be below a temperature that leads to a blanket deposition on both the surface of the metal features 110 and the surface of the dielectric layer 120.

In various embodiments, the gaseous inhibitor material can be deposited on the surfaces over multiple exposure and evacuation cycles, where there can be 1 to 1000 exposure cycles, or 1 to 500 cycles, or 50 to 300 cycles, or 80 to 180 cycles, or 100 to 160 cycles.

In a non-limiting exemplary embodiment, 50 mL of propargylamine was added to a stainless-steel cylinder obtained from STREM Chemicals (#96-1071) and plumbed into an Ultratech Fiji 200 ALD tool. The ALD chamber was held at a constant 25° C. A 10 minute remote nitrogen plasma treatment was carried out on a pre-patterned substrate in the ALD chamber, followed by evacuation. The propargylamine was pulsed for 2.5 sec with a dwell time of 80 sec was then used, followed by a 10 sec evacuation, which was repeated 40 times, before moving the pre-patterned substrates.

At block 650, the chemisorbed inhibitor material can be polymerized to form an inhibiting film on the metal surface. The polymerization reaction may be initiated using a thermal stimulus by increasing the temperature of the chamber, metal features 110, dielectric layer 120 and substrate 105 to a temperature in a range of about 150° C. to about 300° C., or about 200° C. to about 250° C. depending on the chemical properties of the monomers of the inhibitor material.

In various embodiments, the polymerization reaction may be initiated using a photo induced reaction by exposure to light (e.g., laser, discharge lamp, etc.) having a wavelength of less than 250 nm, where the light exposure can break bonds of the polymerizing moiety of the inhibitor material.

In various embodiments, the polymerization reaction may be initiated using a chemically induced reaction utilizing, for example, a Lewis acid, carbocations.

In various embodiments, the inhibiting film can be thinner on the dielectric and thicker on the metal portion of a pre-patterned substrate, where a reducing plasma (e.g., N₂, H₂, or NH₃) can remove the inhibitor from the dielectric surface only (though it may reduce the thickness on the metal) to enable a subsequent area selective deposition on the dielectric surface.

At block 660, the dielectric layer 120 and metal features 110 can be exposed to the gaseous precursors for atomic layer deposition (ALD) of a dielectric film on the exposed surfaces of the dielectric layer 120.

At block 670, the inhibiting film 150 can be removed from the metal feature 110, where the inhibiting film 150 can be removed using a thermal ashing process and/or a plasma etching process that does not remove or damage the surrounding cover layer 160. Additional metallization layers and interlayer dielectric (ILD) layers can be formed on the metal feature(s) in a back-end-of-line process after formation of the cover layer 160 and removal of the inhibiting film 150.

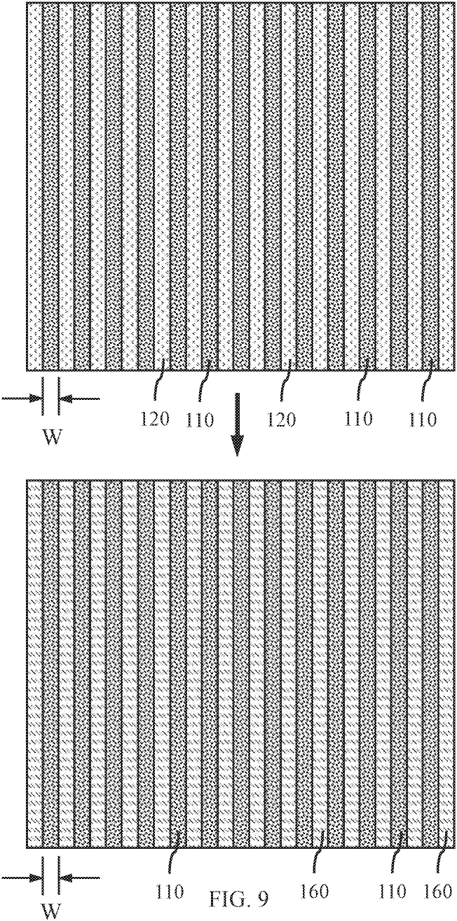

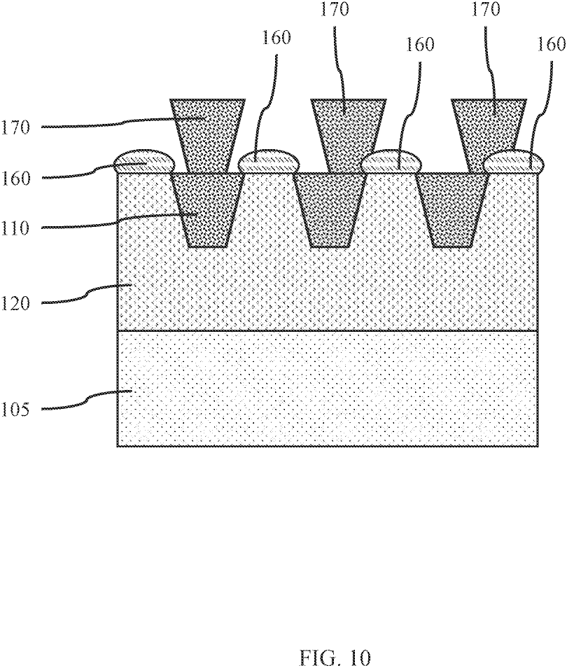

FIG. 9 is a top view showing exposed metal surfaces surrounded by a selectively deposited cover layer material, in accordance with an embodiment of the present invention.

In one or more embodiments, the metal features 110 can have a width, W, in a range of about 20 nanometers (nm) to about 300 nm, or about 30 nm to about 200 nm, or about 40 nm to about 100 nm, although other widths are also contemplated.

In various embodiments, the cover layer 160 can be formed on the dielectric layer 120 alternating with the metal features 110.

FIG. 10 is a cross-sectional side view showing area selective formation of the cover layer on the dielectric surfaces, in accordance with an embodiment of the present invention.

In one or more embodiments, an electrical connection 170 can be formed on one or more of the metal features 110, where the electrical connection 170 may overlap a portion of the cover layer 160 on the dielectric layer 120.

In various embodiments, one or more of the electrical connection 170 can be centered on the metal features 110, where the electrical connection 170 does not contact the cover layer 160. In various embodiments, one or more of the electrical connection 170 can be off-center on the metal features 110, where the electrical connection 170 is in contact with at least a portion of the cover layer 160.

The present embodiments can include a design for an integrated circuit chip, which can be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods as described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ where x is less than or equal to 1, etc. In addition, other elements can be included in the compound and still function in accordance with the present principles. The compounds with additional elements will be referred to herein as alloys.

Reference in the specification to “one embodiment” or “an embodiment”, as well as other variations thereof, means that a particular feature, structure, characteristic, and so forth described in connection with the embodiment is included in at least one embodiment. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” and the like, can be used herein for ease of description to describe one element’s or feature’s relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

Having described preferred embodiments of a device and method (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

What is claimed is:

1. A method of selectively forming a cover layer, comprising:
exposing a surface of a metal feature and a surface of a dielectric layer to a plasma treatment;
exposing the surface of a metal feature and a surface of a dielectric layer to an inhibitor species to form an inhibitor layer selectively on the surface of the metal feature;
polymerizing the inhibitor layer to form an inhibiting film; and
forming the cover layer on the surface of the dielectric layer.

2. The method of claim 1, wherein the metal feature is made of a metal selected from the group consisting of copper (Cu), tungsten (W), and cobalt (Co).

3. The method of claim 2, wherein the inhibitor species is selected from the group consisting of vinylamine, propargylamine, 4-vinylaniline, 2-vinylpyrrole, 4-vinyl pyridine, and 4-vinylpiperidine.

4. The method of claim 3, wherein the inhibitor layer is polymerized using a thermal initiation above a temperature of 100° C.

5. The method of claim 3, wherein the inhibitor layer is polymerized using a photoinitiation using ultraviolet radiation having a wavelength less than 250 nm.

6. The method of claim 3, wherein the inhibitor layer is polymerized using a chemical initiator.

7. The method of claim 3, further comprising exposing the inhibiting film to a reducing plasma, where the reducing plasma reduces the thickness of the inhibiting film.

8. The method of claim 3, wherein the cover layer is a dielectric material selected from the group consisting of zinc oxide (ZnO), tantalum nitride (TaN), and aluminum oxide (AlO).

9. The method of claim 8, wherein the cover layer has a thickness in a range of about 1 nm to about 15 nm.

10. A method of selectively forming a cover layer, comprising:
exposing a surface of a metal feature and a surface of a dielectric layer to a reducing plasma treatment, wherein the metal feature is made of a metal selected from the group consisting of copper (Cu), tungsten (W), and cobalt (Co);
exposing the surface of a metal feature and a surface of a dielectric layer to an inhibitor species to form an inhibitor layer selectively on the surface of the metal feature;
polymerizing the inhibitor layer to form an inhibiting film; and
forming the cover layer on the surface of the dielectric layer.

11. The method of claim 10, wherein the inhibitor species is selected from the group consisting of 4-vinylpyridine, 4-vinylpiperidine, 4-vinylaniline, 2-vinylpyrrole, propargylamine, dipropargylamine, tripropargylamine, vinylamine, N,N-diethnylamine, triethylene amine, 1-amino-3-butyne, 1-amino-3-butene, 1-amino-4-pentyne, and 2-methyl-N-(2-methyl-2-propenyl)-2-propen-1-amine.

12. The method of claim 11, wherein the inhibitor layer is polymerized using a thermal initiation above a temperature of 100° C.

13. The method of claim 11, wherein the inhibitor layer is polymerized using a photoinitiation using ultraviolet radiation having a wavelength less than 250 nm.

14. The method of claim 11, wherein the inhibitor layer is polymerized using a chemical initiator.

15. The method of claim 11, wherein the cover layer is a dielectric material selected from the group consisting of zinc oxide (ZnO), tantalum nitride (TaN), and aluminum oxide (AlO).

16. A method of selectively forming a cover layer, comprising:
exposing a surface of a metal feature and a surface of a dielectric layer to a reducing plasma treatment, wherein the metal feature is made of a metal selected from the group consisting of copper (Cu), tungsten (W), and cobalt (Co);
exposing the surface of a metal feature and a surface of a dielectric layer to an inhibitor species to form an inhibitor layer selectively on the surface of the metal feature;
polymerizing the inhibitor layer to form an inhibiting film; and
forming the cover layer on the surface of the dielectric layer, wherein the cover layer is a dielectric material selected from the group consisting of zinc oxide (ZnO), tantalum nitride (TaN), and aluminum oxide (AlO).

17. The method of claim 16, wherein the cover layer has a thickness in a range of about 1 nm to about 15 nm.

18. The method of claim 17, wherein the inhibitor species is selected from the group consisting of vinylamine, propargylamine, and 4-vinyl pyridine.

19. The method of claim 18, wherein the inhibitor layer is polymerized using a thermal initiation above a temperature of 100° C.

20. The method of claim 18, wherein the inhibitor layer is polymerized using a photoinitiation using ultraviolet radiation having a wavelength less than 250 nm.
